(19) United States
(12) Patent Application Publication
(10) Pub. No.: US 2024/0002682 A1
(43) Pub. Date: Jan. 4, 2024

(54) COATING GRADIENT PROPERTY MANAGEMENT FOR SUSTAINABLE VEHICLES, SYSTEMS, METHODS, AND APPARATUS

(71) Applicant: AYRO, Inc., Round Rock, TX (US)

(72) Inventor: Thomas M. Wittenschlaeger, Sarasota, FL (US)

(21) Appl. No.: 17/936,697

(22) Filed: Sep. 29, 2022

Related U.S. Application Data
(63) Continuation-in-part of application No. 17/810,503, filed on Jul. 1, 2022.

(51) Int. Cl. C09D 5/24; C09D 5/26

(52) U.S. Cl. CPC C09D 5/24; C09D 5/26

(57) ABSTRACT

A system for managing vehicular sustainability is described. Sustainability typically is a broad subject addressed at a high level of abstraction. However, as described herein, sustainability can be managed at a very fine level of detail. More specifically, sustainability of a vehicle can be driven by how one coating of a vehicular surface interacts with a second coating of the surface. Differences in coating properties can give rise to one or more gradient properties (e.g., voltage differences, temperature differences, etc.), which in turn can be leveraged for greater sustainability utility. Such gradient properties can be used to increase the sustainability efficiency of the vehicle at fine levels of detail.

This application is a continuation-in-part of U.S. patent application Ser. No. 17/810,503 titled “Sustainability Validation Systems, Apparatus, and Methods,” filed Jul. 1, 2022. This application also relates to U.S. patent application Ser. No. 17/658,942 titled “Electric Vehicle Control Systems, Apparatus, and Methods,” filed Apr. 12, 2022. U.S. patent application Ser. No. 17/810,503 and U.S. patent application Ser. No. 17/658,942 are incorporated herein by reference in their entireties.

### FIELD OF THE INVENTION

The field of the invention is vehicular coating technologies and more specifically technologies associated with managing gradient properties that arise from differences between coatings with respect to sustainability.

### BACKGROUND

The background description includes information that may be useful in understanding the present inventive subject matter. It is not an admission that any of the information provided herein is prior art or applicant admitted prior art, or relevant to the presently claimed inventive subject matter, or that any publication specifically or implicitly referenced is prior art or applicant admitted prior art.

Sustainability is a broad topic and can take on many different meanings, especially with respect to vehicles; from emissions, fuel efficiencies, to reuse or recyclability. Interestingly, while much work has been focused on the sustainability of vehicles per se with respect to well-known topics such as fuel or reusability, there has been little effort toward more fine-grained sustainability. More specifically, little effort has been applied toward understanding how differences in the properties of coatings deployed on vehicular surfaces can impact sustainability and using the understanding to have an actual impact on a vehicle's sustainability.

A significant amount of effort has been put forth to understand differences between the properties of coatings per se; paints or other materials, with respect to material sciences and with respect to specific use cases, especially in use within batteries. For example, U.S. Pat. No. 10,790,510 to Kim et al. titled “Lithium Ion Battery for Automotive Applications,” filed as a PCT application on Mar. 9, 2017, describes electrodes having layered crystal structures. Still, the purpose of such layers is to drive the performance of the battery. The Kim patent is just one example of battery technology that could relate to vehicles. However, while useful for specific battery applications, Kim fails to appreciate how differences between properties of coatings could have an impact on sustainability of a vehicle.

Still further, coatings may be useful for other purposes in the automotive space beyond batteries. For example, U.S. Pat. No. 11,370,717 to Oboodi et al. titled “Protective Coating Systems for Gas Turbine Engine Applications,” filed Mar. 6, 2020, provides for coatings that create a protective layer with porosity or thermal gradients. However, such gradients, merely provide desired functionality without regard to sustainability.

In the non-automotive space, difference in polymer layers may give rise to functional components. For example, international patent application publication WO 2020/079669 to Deore et al. titled “Functionalized Product Fabricated from a Resin Comprising a Functional Component and a Polymeric Resin, and Method of Making the Same,” filed Oct. 18, 2109, contemplates differences in layers may generate useful properties for 3D printing. While this approach might be applicable in 3D printing, such differences in layers don't necessarily apply to sustainability in vehicles or coatings of target surfaces in vehicles.

What has yet to be appreciated is gradient properties that are generated based on differences in coating properties and that exist between or among coatings impact sustainability, especially with respect to fine levels of sustainability details. The following discussion regarding the inventor's own work, describes how gradient properties from property differences between coatings on a vehicle's surfaces can increase sustainability of vehicles.

All publications identified herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

In some embodiments, the numbers expressing quantities of ingredients, properties such as concentration, reaction conditions, and so forth, used to describe and claim certain embodiments of the inventive subject matter are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the inventive subject matter are approximations, the numerical values set forth in the specific examples are reported as precisely as practicable. The numerical values presented in some embodiments of the inventive subject matter may contain certain errors necessarily resulting from the standard deviation found in their respective testing measurements.

Unless the context dictates the contrary, all ranges set forth herein should be interpreted as being inclusive of their endpoints and open-ended ranges should be interpreted to include only commercially practical values. Similarly, all lists of values should be considered as inclusive of intermediate values unless the context indicates the contrary.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided with respect to certain embodiments herein is intended merely to better illuminate the inventive subject matter and does not pose a limitation on the scope of the inventive subject matter otherwise claimed. No language in the specification should be construed as indicating any non-claimed element essential to the practice of the inventive subject matter.

Groupings of alternative elements or embodiments of the inventive subject matter disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

### SUMMARY

The inventive subject matter provides apparatus, systems, and methods in which a vehicle, especially an electric vehicle and even more preferably an electric low speed vehicle (LSV), can be transformed with respect to sustainability by deploying one or more coatings on the surfaces of the vehicle. Differences in properties of the coatings on the surfaces give rise to one or more gradient properties through which the sustainability of the vehicle is impacted in a positive or desirable manner.

Some embodiments include methods of managing vehicular sustainability efficiency. Such methods may include a step of establishing one or more vehicular sustainability metrics that may be defined as a function of one or more measurable attributes of a vehicle (e.g., friction, electrical potential, lengths, width, toxicity, etc.), especially measurable attributes including gradient properties. The steps further include identifying coating properties of two or more coatings where the coatings target one or more surfaces of the vehicle. For example, coatings may include paint, films, resins, buffers, composites, fabrics, primers, glue, material layers, compound layers, or other types of surface coverings, possibly including temporary coverings (e.g., tarp, tape, adhesives, canvas, magnetic coverings, decals, removable decals, temporary paint, dust, etc.). Differences between or among the properties give rise to one or more gradient properties between or among the coatings. Example gradient properties can include mechanical gradients, thermal gradients, electrical gradients, chemical gradients, biological gradients, acoustic gradients, or other types of gradients. Such gradient properties can be considered distinct manageable properties of the vehicle and that impact sustainability of the vehicle at fine levels of detail. Another step of the method includes measuring a vehicular sustainability metric or metrics based on at least the one or more gradient properties, especially with respect to one or more target surfaces. In some embodiments, a gradient adapter may be coupled between coatings to generate utility from the gradient properties. In the case of an electrical potential gradient, a gradient adapter could be a circuit or battery for example. In other embodiments a gradient adapter might not be necessary; anti-fouling boat hull paints having a toxicity gradient to reduce growth of barnacles for example. If the sustainability metric or metrics satisfies sustainability criteria defined at least in part on the measurable attributes of the vehicle, then the method continues by coating the target surfaces of the vehicle with the coatings to generate the desired level of sustainability. In the case the sustainability metric or metrics fail to satisfy the sustainability criteria, the method can continue by changing the properties of the coatings, identifying different coatings for the surfaces, or leveraging different coating properties and then repeating the process until a desired level of sustainability has been reached.

Various objects, features, aspects, and advantages of the inventive subject matter will become more apparent from the following detailed description of preferred embodiments, along with the accompanying drawing figures in which like numerals represent like components.

### BRIEF DESCRIPTION OF THE DRAWING

FIG. 1 presents an overview a vehicle with coatings that give rise to a gradient property.

FIG. 2 illustrates various coating configurations that can generate a gradient property.

FIG. 3 outlines how measurable attributes may satisfy sustainability criteria.

FIG. 4 illustrates how gradient properties may generate utility via an adapter.

FIG. 5 presents a method managing vehicular sustainability via gradient properties.

### DETAILED DESCRIPTION

It should be noted that any language directed to a computer should be read to include any suitable combination of computing devices, including servers, interfaces, systems, databases, agents, peers, engines, controllers, modules, or other types of computing devices operating individually or collectively. One should appreciate the computing devices comprise a processor configured to execute software instructions stored on a tangible, non-transitory computer readable storage medium (e.g., hard drive, FPGA, PLA, solid state drive, RAM, flash, ROM, etc.). The software instructions configure or program the computing device to provide the roles, responsibilities, or other functionality as discussed below with respect to the disclosed apparatus. Further, the disclosed technologies can be embodied as a computer program product that includes a non-transitory computer readable medium storing the software instructions that causes a processor to execute the disclosed steps associated with implementations of computer-based algorithms, processes, methods, or other instructions. In some embodiments, the various servers, systems, databases, or interfaces exchange data using standardized protocols or algorithms, possibly based on HTTP, HTTPS, AES, public-private key exchanges, web service APIs, known financial transaction protocols, or other electronic information exchanging methods. Data exchanges among devices can be conducted over a packet-switched network, the Internet, LAN, WAN, VPN, or other type of packet switched network; a circuit switched network; cell switched network; or other type of network.

As used in the description herein and throughout the claims that follow, when a system, engine, server, device, module, or other computing element is described as configured to perform or execute functions on data in a memory, the meaning of “configured to” or “programmed to” is defined as one or more processors or cores of the computing element being programmed by a set of software instructions stored in the memory of the computing element to execute the set of functions on target data or data objects stored in the memory.

One should appreciate that the disclosed techniques provide many advantageous technical effects including leveraging or converting differences between coatings into useful properties with respect to sustainability. More specifically, differences between coating properties give rise to one or more gradient properties. Once the coatings are deployed on a vehicle, the resulting gradient properties contribute to a sustainability of the vehicle, which can impact the vehicle's efficiency, the vehicle's environmental footprint, the vehicle's cost, or other vehicular sustainability parameters.

The focus of the disclosed inventive subject matter is to enable construction or configuration of a vehicle having a desired sustainability with respect to desired level of detail, which cannot be achieved without physical modification of a vehicle. Although the following discussion relates to identifying a gradient property, it should be appreciated that such gradient properties can impact the efficiency of the vehicle and a real-world setting in which the vehicle operates. By modifying vehicles or creating such vehicles, especially LSVs, according to the disclosed inventive subject or variations thereof stakeholders associated with the vehicles may enjoy or experience greater sustainable utility of the vehicle.

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

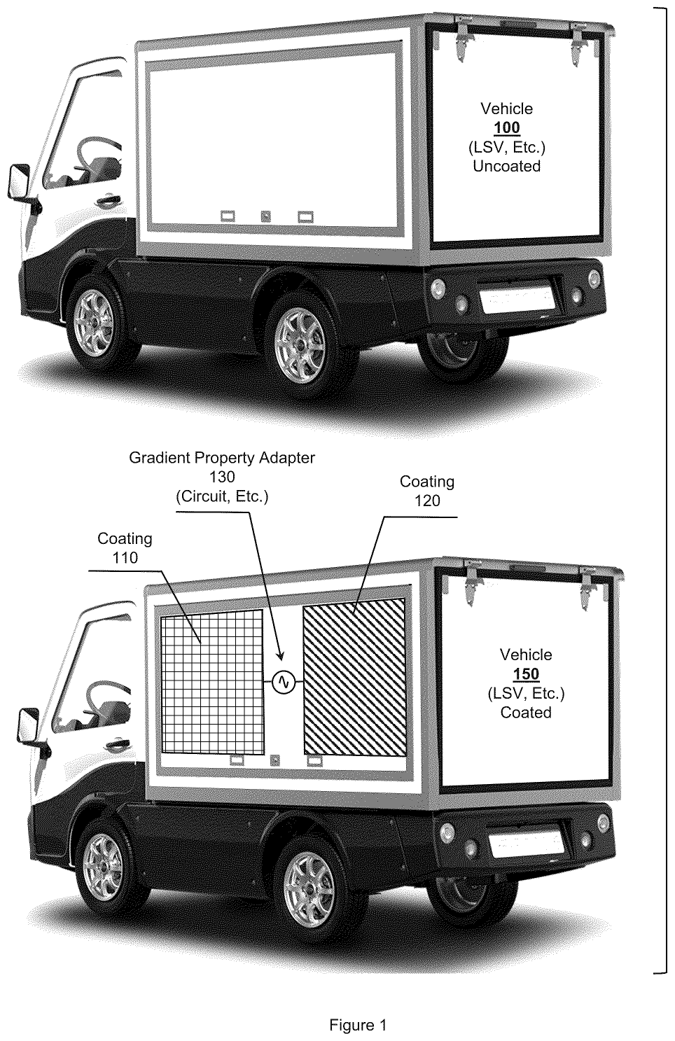

FIG. 1 illustrates deployment of the disclosed inventive subject matter on electric LSVs. The inventors are pioneering sustainability in LSVs, especially with a focus on fine levels of sustainability detail. The following discussion relates specifically to the coatings that may be used in covering target surfaces of a vehicle, especially LSVs. More specifically, while coatings may be considered by others to be of no interest with respect to sustainability, the inventors have discovered and appreciated that even minimal differences between the properties of coatings can impact the sustainability of a vehicle, a fleet of vehicles, or even vehicular environments. The LSVs shown are from Ayro, Inc., (see URL www.ayro.com), the applicant, which provides state of the art low costs, high efficiency LSVs to the market.

Vehicle 100 represents an unmodified vehicle that lacks use of the inventive subject matter as disclosed herein. As illustrated, a more preferred target vehicle comprises an electric LSV, which may already have a high degree of sustainability. For example, Ayro, Inc. is a pioneer in the electric LSV sustainable vehicle space. Still, as described herein, additional efficiencies can be achieved to push the utility of sustainability even further at fine levels of detail.

Vehicle 150 represents a modified vehicle (e.g., manufactured according to the disclosed subject matter, field upgraded, etc.) having coatings applied according to the inventive subject matter. In the example shown, vehicle 150 comprises one or more target surfaces that are coated with at least two coatings; coating 110 and coating 120, for example. Differences in properties of the coatings, say differences in ability to absorb heat from the sun, may give rise to the gradient property; a thermal gradient in the current example. In such an embodiment, the coatings may be coupled via one or more gradient property adapter 130, a thermocouple for example, which may be used to generate electrical energy for the vehicle. Generation, storage, or use of such energy aids in reducing the environmental impact of the vehicle and can increase sustainability.

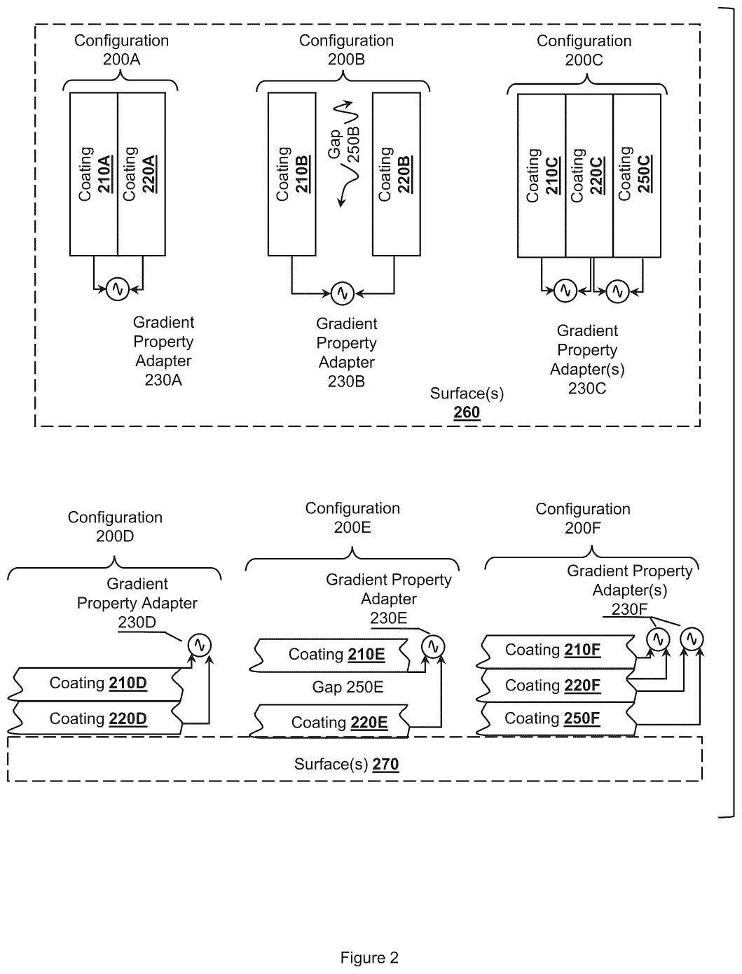

FIG. 2 presents various example configurations of coatings by which one can leverage the inventive subject matter to generate a vehicle having higher sustainability according to some embodiments of the disclosure. While FIG. 2 presents a few configurations for illustrative purposes, one should appreciate that other configurations may be possible beyond those shown without departing from the nature of the inventive subject matter. The two types of configurations shown illustrate coatings placed next to each other on surface 260 and coatings stacked or layered on each other upon surface 270.

Surface 260 configurations illustrate how coatings may be juxtaposed relative to each and where both are deposited directly on the same target surface. Configuration 200A represents a configuration where coatings 210A and 220A are directly next to each other to the point where they may contact each other. For example, coating 210A could be a first type of paint, while coating 220A could be a second, different type of paint. In this case, the two coatings may be coupled to each other via gradient property adapter 230A that leverages the differences in properties between the two coatings to contribute to sustainability. Consider a case where a surface of an LSV, a roof for example, where the roof has been painted with alternating stripes of reflective white paint (or other suitable coating) and matte black paint (or other suitable coating). During sunny weather, the black paint area might heat up while the white paint may be cooler. In such a case, gradient property adapter 230A could comprises a thermocouple, subject to temperature requirements, to convert the thermal gradient into an electrical voltage.

Configuration 200B presents another possible configuration where coating 210B and coating 220B are separated by gap 250B. In this case, the gradient property adapter might exist in the gap or even deployed distal to surface 260 while remaining coupled with the coatings to tap into the gradient. Gap 250B may be leveraged in some scenarios to provide for or enhance the desired gradient property. For example, gap 250B may exist between two coatings 210B and 220B, which expand or contract with temperature. In such cases, gradient property adapter 230B might include a mechanical spring, a piezoelectric sensor, or other device capable of converting a mechanical gradient into work, sensed data, or even electrical energy.

Configuration 200C provides yet another configuration where there are three coatings, one next to another as shown with coating 210C next to coating 220C, which in turn is next to coating 250C. In such a configuration, one or more gradient adapters 230C may be placed between the coatings. In the case shown, adapters 230C are placed between neighboring coatings. However, one should appreciate such adapters could be disposed or coupled between any different coatings where a gradient property may exist.

Surface 270 represents a target surface on which coatings may be stacked or layered on top of each other (e.g., primer, paint, sealant, etc.). Configuration 200D illustrates coating 220D is placed on surface 270 and coating 210D is then disposed on coating 220D. Such a configuration may be applicable for layering coats of paint, decals, magnetic materials, or other layered coatings. In this example, gradient adapted 230D may be placed so that it couples with each layer in an appropriate manner. For example, coating 220D and 210D might represent forms of solar hydrogen paint, photovoltaic paint, or perovskite solar paint, which provide for collecting solar energy. Thus, gradient property adapter 230D could comprise a circuit, possibly including a battery, that operates based on a voltage differential among the layers.

Configuration 200E provides a similar structure to configuration 200B, except coating 210E is placed over coating 220E with intermediary gap 250E. While in some embodiments gap 250E may not be practical (e.g., only paint, etc.), in other embodiments where coatings 210E are more rigid (e.g., physical coverings, etc.) coating 210E may be placed on risers. For example, in some embodiments, gap 250E could be considered an air plenum. In such a case, as a vehicle moves, air will flow through gap 250E. The air flow can then flow over gradient property adapter 250E (e.g., a turbine, propeller, impeller, etc.), which when coupled with a generator can generate electricity. Alternatively, plenums may also reduce drag by creating controlled air pathways in or around the vehicle.

Configuration 200F is similar to configuration 200E except that all three coatings are stacked on surface 270, one on top of another. As illustrated, coating 250F may be disposed directly on surface 270, coating 220F may then be placed on coating 250F, and coating 210F may be placed on coating 220F. One should appreciate any number of layers may be used as may be practical for the sustainability requirements. Further gradient adapters 230F are presented as coupled neighboring layers. However, as with configuration 200C, gradient property adapters 230F may couple any layer or layers to any other layer or layers.

Surfaces 260 and 270 may be any practical surface of a vehicle (such as the vehicle 150). In some embodiments, a target surface is an external surface of a vehicle, which may be typically exposed to the environment (e.g., heat, sun, wind, moisture, people, etc.), which may contribute to generation of a desired gradient property. The surfaces of a vehicle can include a roof, side panels, a hood, a tail gate, a cargo bed, tire surfaces, or other types of external surfaces. In some cases, the external surfaces could be a temporary surface possibly including tarps, removable panels, removable doors, convertible roof, magnetic panel or signs, or other types of temporary surfaces.

In other embodiments, surfaces 260 and 270 could also include internal surfaces, which are not typically exposed to the environment. For example, internal surfaces could be part of or in the engine or motor, surfaces in the cab or passenger area, surfaces internal to the paneling or doors, or other surfaces that are not typically exposed to the environment. However, internal surfaces may still leverage conditions that aid in generating gradient properties; temperature differences, for example.

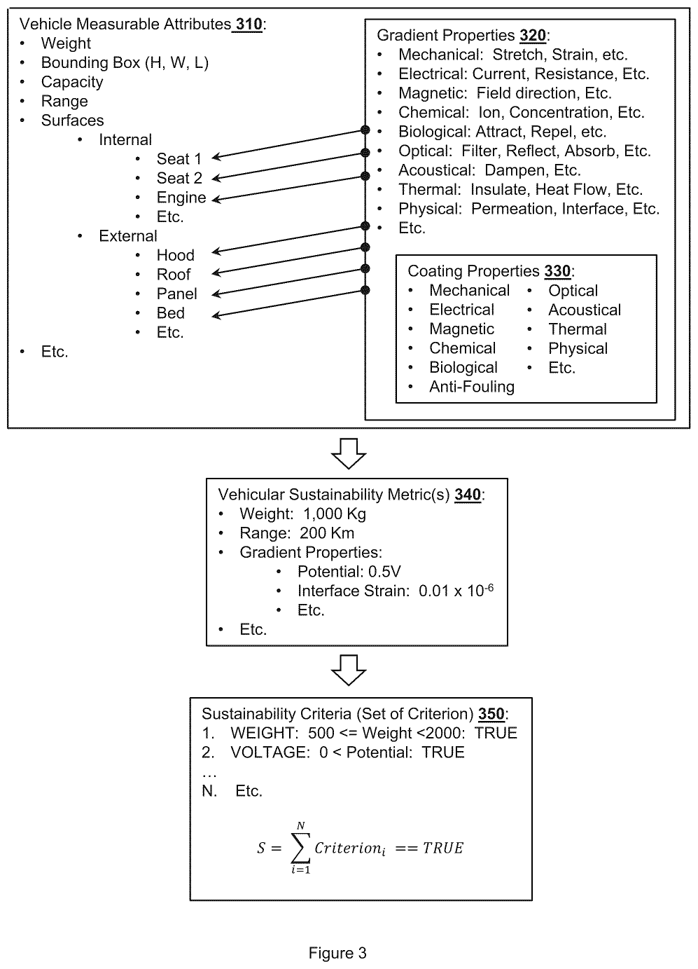

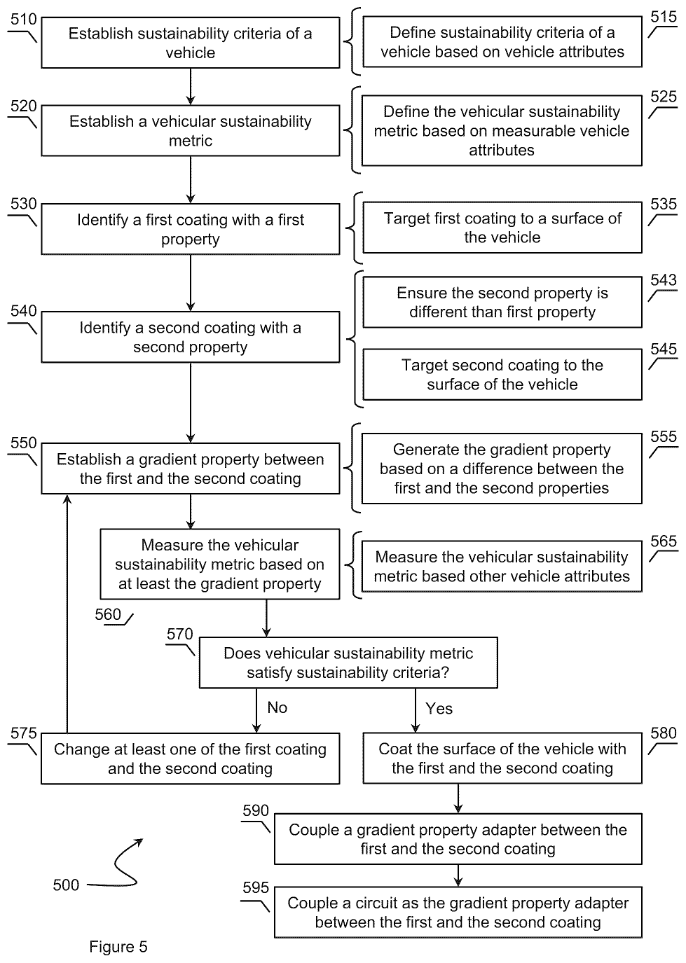

FIG. 3 illustrates ways vehicle measurable attributes 310, including gradient properties 320, may give rise to a more sustainable vehicle when properly managed. Typically, the inventive subject may start with defining desirable sustainability criteria 350 for a target vehicle, fleet of vehicles, the manufacturing of vehicles, or other set of vehicles (see also FIG. 5 and associated discussion).

In the example shown in FIG. 3, a vehicle may be characterized via one or more of vehicle measurable attributes 310. Vehicle measurable attributes 310 can comprise a broad spectrum of information, especially in view the values of the attributes can relate to sustainability. More information regarding fine-grained analysis of sustainability can be found in co-owned applications U.S. patent application Ser. No. 17/658,942 titled “Electric Vehicle Control Systems, Apparatus, and Methods,” filed Apr. 12, 2022, and U.S. patent application Ser. No. 17/810,503 titled “Sustainability Validation Systems, Apparatus, and Methods,” filed Jul. 1, 2022, all of which are incorporated by reference herein in their entireties. For example, measurable attributes 310 can include weight, bounding box, passenger capacity, carrying capacity, range, battery information (e.g., number of batteries, type of batteries, charge, etc.), carbon footprint or other attributes that may be quantified. Of particular interest with respect to the inventive subject matter, the measurable attributes 310 can further relate to surfaces of the vehicle, including internal or external surfaces. More specifically, the measurable attributes can include coating properties 330 of the coatings that target the various surfaces of the vehicle.

Coating properties 330 relate to the nature of or the material of the corresponding coating. Depending on the nature of the actual coating and the sustainability needs, coating properties 330 can also vary across a vast set of property types. As illustrated, examples of coating properties 330 can include mechanical properties (e.g., stress, strain, elasticity, etc.), electrical properties (e.g., resistance, capacitance, inductance, etc.), magnetic properties, chemical properties (e.g., pH, reactivity, etc.), biological properties (e.g., toxicity, etc.), anti-fouling properties, optical properties, acoustic properties, thermal properties, physical properties, or other types of properties.

Differences in coating properties 330 between or among the coatings can give rise to one or more gradient properties 320. For example, differences in mechanical properties could cause stress or strains across a target surface, which may be leveraged for work or other utility that may impact sustainability. While gradient properties 320 may align with the underlying coating properties 330, the two do not necessarily have to be equivalent. For example, mechanical gradient properties (e.g., stress, strain, etc.) could arise from differences in thermal properties of the coatings as the coatings or surfaces expand or contract as the vehicle's temperature changes along with changes in temperature of the environment.

As illustrated, one or more vehicular sustainability metrics 340 may be generated from the measurable attributes 310. In some embodiments, the sustainability metric 340 represents the values measured from the attributes as illustrated. More preferably, the sustainability metrics 340 further include the measured values associated with the gradient properties 320 as they specifically relate to the desirable sustainability features according to the inventive subject matter. For example, a gradient property might comprise an electrical potential of 0.5V, which may be used to drive electric circuits (i.e., gradient property adapters).

While gradient properties 320 are listed in a static form, one should appreciate gradient properties 320 can vary with time or other circumstances. For example, as the vehicle moves around an environment, the surfaces of the vehicle and the corresponding coatings may heat or cool thereby expanding or contracting the surface or the coatings, which could change the gradient properties 320 with time or temperature. Changes in temperature could occur for one or more reasons including moving from a sunlit area to a shadow, changes in weather, rain, or other conditions. In other cases, as the vehicle moves about, the surfaces may bend, stretch, rotate, or otherwise shift or change. In which case, corresponding mechanical gradient properties may change. Thus, gradient properties 320 can be consider dynamic in nature. Therefore, vehicular sustainability metrics 340 may include one or more derivatives of measured values, including derivatives of gradient properties 320. The derivatives may include time-based derivatives (e.g., dx/dt, d²x/dt², d³x/dt³, d⁴x/dt⁴, etc.) where X is gradient property, or derivatives with respect to various properties that might change (e.g., dx/dy, d²x/dy², d³x/dy³, d⁴x/dy⁴, etc.) where Y is another property other than time that can change as the environment changes (e.g., temperature, force, etc.).

Vehicular sustainability metrics 340 may then be used to establish if the sustainability criteria 350 are satisfied. In the example shown, sustainability criteria 350 comprises multiple individual criterions, which can be combined as desired using various logical operators, functions, or other techniques. For example, criterion 2 illustrates that a voltage (i.e., one of gradient properties 320) of coatings of a target surface is greater than 0V. In the case of FIG. 3, criterion 2 is TRUE.

Satisfaction of sustainability criteria 350 can be determined many ways. Still, in the example show, if all individual criterions are TRUE, then sustainability criteria 350 is TRUE. However, other factors may influence the satisfaction of sustainability criteria 350 beyond simply having all criterion be TRUE. For example, some criterion might be “optional” in the sense that if the criteria fail to be satisfied, the final satisfaction might still be TRUE. Perhaps, at any given time only a certain number of criterions might be allowed to fail their conditions, say five criterions of out 20, while all others must be satisfied.

Satisfaction of the sustainability criteria 350 can be represented by one or more values. The satisfaction could represent a count of criterion that are satisfied. Other forms of measuring satisfaction are also contemplated including measuring a distance between an ideal sustainability derived from gradient properties 320 and the current set of metrics in an N-dimensional space characterized by the sustainability metrics 340 or characterized by sustainability criteria 350. Such a distance could be represented as a Euclidean distance between the two points in the N-dimensional space. Satisfaction could also be measured via a Hamming distance, which could indicate the number of changes in the metrics required to meet the minimum number, desired number, or optimal number of sustainability criterion that are satisfied.

From a different perspective, an astute reader will appreciate that use of sustainability metric 340 and sustainability criteria 350 could take on different forms. For example, sustainability criteria 350 could be set based directly on the gradient properties and the sustainability metrics could then be the measure of satisfaction as derived from which sustainability criterion or criteria are satisfied or not satisfied. Thus, in some embodiments, the sustainability metric 340 and sustainability criteria 350 might be considered swapped. That is, sustainability criteria 350 is used to generate sustainability metric 340 rather than sustainability metric 340 being used to establish sustainability criteria 350 as illustrated.

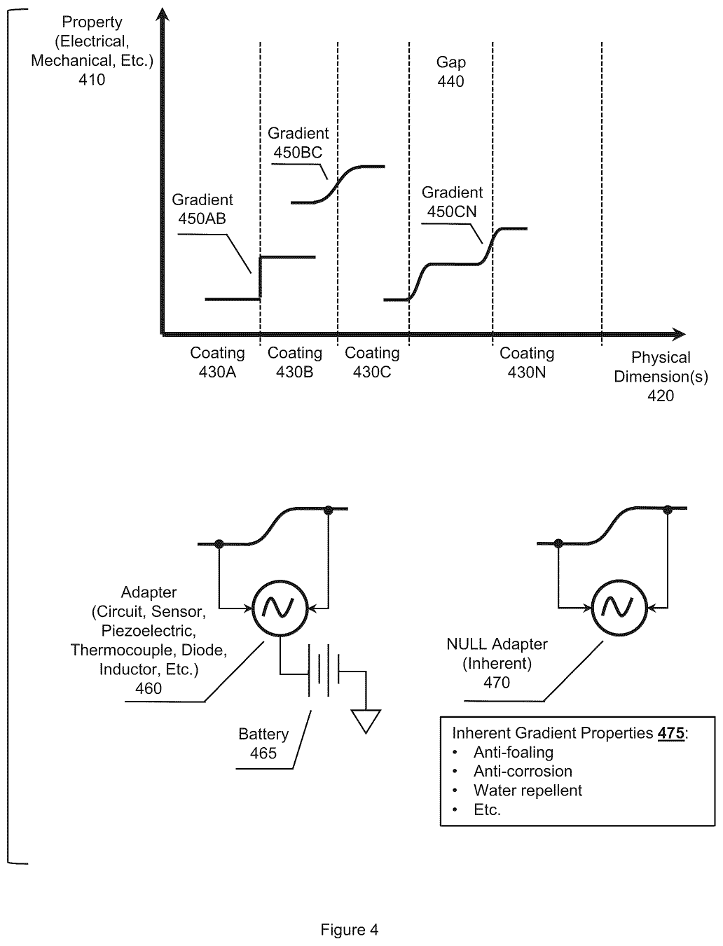

FIG. 4 presents a more detailed review of gradient properties from the perspective of how one or more gradients behave across boundary conditions. The horizontal axis represents position on a surface or other relative physical dimension 420. The vertical axis represents a value of a coating property 410 (e.g., electrical property, mechanical property, chemical property, etc.). Thus, according to the inventive subject matter, property 410 may change as represented by gradients 450. The graph in FIG. 4 is presented to illustrate the varied nature gradient properties can take depending on the nature of the underlying coatings. While the gradients are shown as increasing in the value of property 410 as one moves toward the right in the physical dimension 420, it should be appreciated the value of property 410 could just as easily decrease. Thus, the graph in FIG. 4 is not consider limiting.

First, consider coatings 430A and 430B that are directly next to each other. These two coatings could be any practical set of coatings that gives rise to one or more differences in one or more of property 410. In this example, gradient 450AB represents a step function where the corresponding gradient property shifts from one value of property 410 to another property 410 at the boundary between the two coatings or where to two coatings meet. For example, gradient 450AB could comprise a change in a chemical property across the boundary or an anti-fouling agent on a boat.

Now consider coating 430B next to coating 430C. In this case, gradient 450BC represents a continuous change in the value of property 410 across the boundary. First, starting at the interior of coating 430B, property 410 remains substantially fixed. However, property 410 begins to change as the boundary between the coatings is approached and continues to change within coating 430C until it may stabilize in the interior of coating 430C. For example, the coating 430B and 430C might comprise differences in capability of reflecting or absorbing solar heat. In such a case, property 410 would be temperature. Thus, one aspect of the inventive subject is to size or dimension the coatings to generate a gradient property having the desired characteristics for better sustainability (e.g., desired gradient curve, desired distance, desired min, desired max, desired difference, etc.).

Gradient 450CN illustrates another configuration where coating 430C and 430N are separated by gap 440. In this case, gradient 450CN might have a shift in property 410 across gap 440 as well. Such situations may arise in coating configurations where gap 440 could comprise an air gap, an insulator, or other types of separators. For example, gap 440 might be, more or less, an air gap, where a physical device is disposed between coating 430C and coating 430N; a spring or piezoelectric device or sensor, for example.

FIG. 4 also presents example gradient adapters for further clarity. In the case for adapter 460, gradient adapter 460 taps into differences across the illustrated coating property. One should appreciate gradient adapter 460 may contact coatings or otherwise couple to the coatings at any favorable point, not just at the boundaries. In the case of gradient adapter 460, gradient adapter 460 couples to the coatings where the gradient property is at its maximum difference. In this case, gradient adapter 460 could comprise a circuit, a sensor, a piezoelectric device, a thermocouple, a diode, a whetstone bridge, an inductor, a thermal circuit, or other device through which sustainability parameters may be achieved. In the example shown, gradient adapter 460 may couple to one or more of battery 465 for storing electrical energy derived from the gradient property and generated by gradient adapter 460.

While gradient adapters may be physical devices that contribute to sustainability, it is also possible that a gradient property might inherently have value with respect to sustainability. For example, gradient adapter 470 is a NULL adapter, indicating no physical device is necessary. However, it is still shown as the gradient adapter could be provisioned with one or more sensors to monitor, possibly in real-time, the status of the gradient property with respect to sustainability criteria. Such sensors may be coupled with one or more computing devices to report on the status of the coatings with respect to sustainability. Examples of situations where a NULL adapter might be applicable include anti-corrosion coatings, water repellent coatings, anti-fouling coatings for boats, or situations where difference in coating properties do not require a specific device to give rise to desirable sustainability features, but still may need to be monitored via a sensor.

FIG. 5 presents a method of managing the sustainability efficiency of a vehicle through the impact of vehicular coatings on sustainability. Method 500 may start with step 510, which includes establishing or otherwise defining sustainability criteria for a vehicle. One should note the inventors have pioneered a new perspective of sustainability by appreciating that vehicle sustainability can depend on a myriad of factors or contexts, even at a fine level of detail. Further, they have appreciated global sustainability can, in many ways, be critical to the environment more than local sustainability. Said differently, creating a single sustainable vehicle (i.e., local optimization) may come at the expense of creating a fleet of sustainable vehicles (i.e., global optimization) because, among other reasons, the resources for creating a single vehicle might not consider the full global impact of operating, producing, or manufacturing all of the vehicles. Additional details regarding the inventor's discoveries regarding fine-grain sustainability can be found in U.S. patent application Ser. No. 17/658,942 titled “Electric Vehicle Control Systems, Apparatus, and Methods,” filed Apr. 12, 2022, and U.S. patent application Ser. No. 17/810,503 titled “Sustainability Validation Systems, Apparatus, and Methods,” filed Jul. 1, 2022, all of which are incorporated by reference herein in their entireties. Thus, step 510 can include creating sustainability criteria that can depend on many parameters or factors associated with the vehicle. Typically, the criteria can include one or more individual criterion that are defined based on the factors. For example, the criterion can be defined based on ranges of values, thresholds of values (e.g., falling below a low threshold, exceeding a high threshold, etc.). Further, criteria can include logical or Boolean operators such as AND, OR, IF-THEN-ELSE, XOR, or other type of logical operators. Still further, criterion may be coupled to one another with logical operators. The criterion or criteria can also depend on more complex functions, possibly operating on a computer, where measurable values are provided as input and the functions generate satisfaction outputs based on the definition of the functions (e.g., mathematical functions, look up tables, Monte Carlo simulations, etc.). Thus, the sustainability criteria can be arbitrarily complex, at least to the limits of practicality. Typically, a criterion can include required conditions. Still, it is also possible that a criterion can include optional conditions. Such optional conditions may not impact the overall satisfaction of the sustainability criteria; however, the optional conditional may impact an overall vehicular sustainability metric or sustainability satisfaction metric.

From a more detailed perspective the sustainability criteria may be defined based on the vehicular attributes, especially with respect to measurable attributes as indicated by step 515. Of particular interest, the measurable attributes of the vehicle preferably include values that quantify properties of the coatings used to coat surfaces of the vehicle. Differences in the properties can also generate gradient properties across the coatings, which are also measurable and that may otherwise be present on the vehicle. Therefore, the gradient properties can also be considered measurable attributes of the vehicle and can be used for defining sustainability criteria (see FIG. 3, for example).

In addition to defining sustainability criteria, method 500 can also include establishing a vehicular sustainability metric at step 520, which can indicate to what level the sustainability criteria are satisfied. In some embodiments, the metric may be binary (e.g., satisfied vs. not satisfied, TRUE vs. FALSE, 0 vs. 1, etc.) simply indicating the overall state of the vehicle satisfies the criteria, especially with respect to coatings. However, in other more interesting embodiments, the metric can take on more nuanced aspects beyond simply a binary result. The metric can take on a broad spectrum of values, value types, or even multiple values. In some cases, the metric could be a range indicating the degree to which the criteria are satisfied or is not satisfied (e.g., 0.0 to 1.0; 0 to 10, 0 to 100, −1 to 1, normalized values, etc.), which can be calculated based on the individual criterion, weightings, or other factors. Still further, criteria could include other types of data beyond numbers, possibly including images (e.g., graphs, charts, gauges, etc.) or even text. Even further, the metric can include multi-valued metrics possibly where each criteria includes its own metric or where each criteria are organized hierarchically, where the values include an average with standard deviation, or other values. In some embodiments, the metrics may be derived from a look-up table, or derived from a computer-implemented function.

Just as the sustainability criteria can be defined based on the measurable vehicular attributes, at step 525, the sustainability metric can also be defined based on the measurable attributes of the vehicle. The individual values of the attributes may contribute directly to the metric via a computer-based calculation or function, for example, possibly based on real-time gradient property sensor data. Alternatively, the metric can be calculated based on the values of the attributes in aggregate or in any combination. For example, the metric can be calculated via a computer-implemented function that takes the values of the attributes as input and converts them to the desired metric via one or more calculations or computer operations. Such functions can be based on mathematical calculations, look-up tables, evaluation by 3r d parties, machine learning systems, or other types of computer-based functions. In some embodiments, the functions governing the behavior of the criteria and metrics can be the same function. In fact, in some embodiments, such functions can also operate on dynamic properties of the vehicle including age of the vehicle (i.e., time), vehicular location, vehicular context, or other types of vehicular attributes that can change as the vehicle operates.

At this point in method 500 the sustainability criteria and desirable metrics are understood with respect to the sustainability of the vehicle. Thus, coating-based impacts of sustainability can be undertaken at step 530. Step 530 includes identifying a first coating (e.g., paint, film, tape, covering, decal, grease, putty, etc.) along with a desirable corresponding first coating property (e.g., capacitance, resistance, inductance, toxicity, stress, strain, thermal capacity, etc.). Further, at step 535 the first coating may be targeted toward a specific vehicle surface. The surfaces may typically be an external surface of the vehicle (e.g., cargo bed, roof, panel, door, window, etc.). However, it is also possible the target surface may be an internal surface (e.g., a cab surface, a seat, an engine surface, an internal tire surface, etc.).

To generate a gradient or differential property among the coatings, step 540 includes identifying a second coating with a second property. While the first property and the second property are typically of the same type of properties, it is also possible that the two properties could be of different types (e.g., thermal versus electrical, etc.). Still, and more specifically, the first property and the second operation should be different with respect to their values (e.g., differences in potential, differences in thermal conduction, etc.) as indicated by step 543, wherein the difference will generate at least one gradient property. In view that method 500 is seeking to leverage gradient properties for sustainability, the second coating should also target a surface of the vehicle, likely the same surface targeted by the first coating. One should keep in mind, as described with respect to FIG. 2, numerous geometries of coatings relative to the surfaces are contemplated.

One should appreciate while coating types and their properties can be quite varied, the core concept here is not necessarily just the property itself, but the interaction of the property with other aspects of the vehicle and with respect to sustainability. From a hierarchical sense, as described with respect to method 500, one can first start with a sustainability goal, which then can be used to define quantifiable values that impact sustainability. The quantifiable values can then dictate which gradient properties would be most useful. Further, the gradient properties can be used to establish or determine which coating properties would be of most use for the sustainability goals. In some embodiments, the decisions may be repeated until the expected sustainability coverages on a desirable value based on a set of coatings selected.

Step 550 includes establishing one or more gradient properties between or among at least the first and the second coatings. As discussed previously, the gradient property can comprise a broad spectrum of types including mechanical gradients, thermal gradients, electrical gradients, chemical gradients, toxicity gradients, biological gradients, or other types or categories of gradients. Typically, as indicated by step 555 and alluded to above, the gradient properties are generated based on differences between the first property of the first coating and the second property of the second coating. Again, as stated above, one aspect of the inventive subject matter is generating sustainability based on a gradient property, rather than merely generating the gradient property by itself.

Turning toward step 560, the gradient property can be quantified. More specifically, the method includes measuring the vehicular sustainability metric based on at least the gradient property. This step ties back to the beginning of the method where the sustainability requirements are established and seeks to ensure the original sustainability goals are being met. While the gradient property is used to measure the sustainability, it is also possible for other quantified attributes to contribute the sustainability metric. Thus, it should be appreciated that while a gradient property contributes to sustainability it may not be the sole contribution because other factors may be used to ensure the vehicle as a whole, a vehicular fleet as a whole, or even a global group of manufactured vehicles as a whole meet sustainability requirements based on all relevant quantified vehicular attributes as indicate by step 565.

Step 570 includes determining whether the sustainability goals have been met or not. If the sustainability metric satisfies the sustainability criteria, method 500 proceeds toward step 580. If the sustainability metric fails to satisfy the sustainability criteria, method 500 proceeds toward step 575. As discussed previously the sustainability criteria can be quite complex and the corresponding metric could be similarly complex. Thus, the decision point represented by step 570 can be implemented by one or more computer-implemented functions that yield binary output (i.e., criteria satisfied vs. criteria not-satisfied). Such functions can receive input in the form of the metrics and possibly including other vehicular information as well (e.g., values of attributes, vehicular context, operator information, owner information, etc.). The functions can then evaluate the information through various techniques including look-up tables, calculations, database queries, or other techniques or combinations thereof.

Consider the case where the sustainability criteria are not satisfied, method 500 moves toward step 575, which includes changing at least one of the first and the second coatings. Which could possibly include altering of the properties of the first and the second coatings in order to drive the system toward a more desirable sustainability result. Once one or more changes have been made, control of the method can return to step 550 to repeat the analysis. One of the advantages of such a process is that it provides for verifying experimentally that the coatings, and their resulting gradient properties, achieve the desired sustainability goals. Experiments can be conducted empirically via real-world testing, computer simulations, Monte Carlo simulations, or combinations thereof.

Now consider the case where the sustainability metric satisfies the sustainability criteria, control of method 500 may move to step 580. Step 580 includes deploying the coatings on the vehicle by coating the target surface or surfaces with the first and the second coating. Coating the surfaces depends on the nature of the coatings themselves and can also depend on the desired geometry or configurations of the coatings to achieve the desired gradient property result. In the case of paint, primers, sealants, or other similar types of coatings, the first coating may be sprayed on the surface first, and then the second coating can be applied over the first coating. However, in other cases, coatings may be temporary (e.g., magnetic coverings, films, adhesives, etc.). Still, in other cases coating the surface might include sputtering material on the surface before the vehicle is fully assembled. Still further, the act of coating may be done after assembly or even after deployment and in the operating environment of the vehicle. For example, applying the coating to the surface could occur as field maintenance or as a sustainability upgrade after being deployed. More specifically, the coatings may be a field upgrade in the form of magnetic sheets that may be applied directly to the metal surfaces of the vehicle. Each sheet may be applied and then the sheets may be coupled via a gradient adapter. Thus, one aspect of the inventive subject matter is considered to include kits having have prepared coatings and suitable gradient adapters. Such kits may be useful, for example, in leveraging magnetic flexible solar arrays, magnetic flexible thermal sheets, magnetic sheets with LED displays, or other types of magnetic sheet upgrades.

Some embodiments may also include coupling a gradient property adapter between or across the first and the second coating as indicated by step 590. The gradient property adapter provides leveraging the gradient property toward specific sustainability utility. For example, in some embodiments the gradient property adapter may be configured to convert the differences between the properties of the first and the second coatings into work, electricity, or other functional elements. Gradient property adapters would depend on the nature of the coatings, and in some cases may not be necessary. Consider a scenario where the gradient property comprises an electrical potential difference. In such cases the gradient property adapter could comprise a battery, or accompanying circuits, to store electrical energy generated by the difference between the coatings. In a similar vein the adapter could comprise a thermocouple to generate electrical energy when the gradient property comprises a sufficient thermal difference between the coatings. More specifically, the gradient property adapter can comprise a circuit as suggested by step 595, which can covert a voltage difference into practical applications (e.g., light, sounds, wireless transmission, etc.).

The above discussion relates to various fundamental aspects of the inventive subject matter. Still, beyond the fundamental features described above, there are numerous additional considerations or variations relating to the subject matter as described below.

Beyond passive coatings as described above, some embodiments may include active coatings that may change behavior as circumstances changes (e.g., time passes, under command or control of stakeholders, etc.). Some active coatings may change their fundamental properties as temperature changes for example (discussed above). Still other may take on more active roles. For example, a coating could comprise one or more sheets, possibly magnetic sheets, of LEDs that leverage gradient properties to cause the LEDs of the sheets to render a displayed image, color, pattern, or other light-based displays. Such an approach aids in creating vehicles that provide for sustainability features relating to visual appearance. More specifically, and as discussed in the sister applications, the visual appearance of the sheets may cause the vehicle to blend into the background to reduce the visual disturbance of the vehicle. Another active coating could include an electrostatic coating capable of repelling dust from the surface of the vehicle. Repelling dust provides for keeping the vehicle clean, which can reduce use of water or can reduce wear and tear of the vehicle and thereby increasing the vehicles sustainability. Yet another active coating may include use of noise canceling coatings to reduce or muffle noises generated by the vehicle during operation.

Yet another interesting aspect of the inventive subject matter includes treating the gradient properties of the coatings as a distinct manageable object from the perspective of computer science. Said differently, digital information related to the vehicle can include one or more instantiated gradient property objects stored in a memory of a computer, possibly as part of the vehicle management system installed on the vehicle. In such cases, the computer may be provisioned with known gradient properties, likely defined at design or manufacturing time, or provisioned with newly defined gradient properties as field upgrades or custom defined gradient properties. From a technical perspective, gradient property objects may be instantiated from one or more class definitions which include corresponding class methods or properties. The computer can further couple to the gradient property objects via one or more APIs through which the computer can determine if the gradient property is indeed contributing as expected. For example, one or more gradient property listeners may be registered with the operating system or sustainability application. As corresponding gradient properties change, the listeners may be triggered upon satisfaction of the activation criteria, possibly based on sensor data. When activated, the listeners can then take action, possibly including generating alerts or notifications, logging sustainability events, running a diagnostic, or other types of actions.

While the main discussion above focused on surfaces per se, one should appreciate that any surface could be targeted, including tires or treads. For example, the internal portions of a tire could be instrumented with one or more coatings (e.g., piezoelectric materials, etc.) that generate voltage differentials based on stress, strain, compression, or other mechanical forces. As the vehicle travels around the operating environment the tires will flex under the weight of the vehicle. In response, the voltage differences between the coatings may be used to harvest electrical power possibly for storage, for lighting LEDs, or other purposes.

Additional coating features that could contribute sustainability can include color, size, shape, adhesive material, or just about any other attribute of the coating. Further, differences in coatings can include differences in material (e.g., metal vs. bamboo), differences in color, differences density, differences in porosity, or other differences that could give rise to desirable gradient properties. For example, a first coating might include one or more insulation layers while a second coating might include one or more shielding layers or emitting layers (e.g., LEDs, etc.).

Previously, the reader was directed to consider differences between local optimization and global optimization. To further this point, one should also appreciate the inventive subject matter is considered to include determining a tradeoff between one set of features of sustainability versus another set of features. For example, in some cases coatings may be less biocompatible with the environment (i.e., less sustainable at a local level) while offering greater impact at manufacturing time due to reduce costs or impact in obtaining the coating material. Thus, the overall impact on the environment as a whole is reduced at the expense of an increased local impact. From a slightly different perspective, the tradeoff between providing less desirable gradient properties may also extend the life of the vehicle. If a vehicle's life is extended, then there is less need to replace the vehicle. Which, in turn, reduces the need for disposal or replacement. Thus, at the expense of one less sustainable property one gains sustainability over the lifetime of the vehicle or over the use of a fleet of vehicles.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification or claims refer to at least one of something selected from the group consisting of A, B, C . . . and N, the text should be interpreted as requiring only one element from the group, not A plus N, or B plus N, etc.

1. A method of managing vehicular sustainability efficiency, the method comprising:
establishing a vehicular sustainability metric as a function of a plurality of measurable attributes across a plurality of surfaces of a vehicle;
identifying a first coating having a first property, the first coating targeting a surface of the vehicle;
identifying a second coating having a second property, the second coating targeting the surface of the vehicle;
determining a gradient property between the first coating and the second coating based on a difference between the first property and the second property, wherein the first coating and the second coating are electrically coupled via a gradient adaptor configured to capture a potential energy generated based on the gradient property;
measuring, for the vehicle, the vehicular sustainability metric as a function of at least the gradient property with respect to the surface and the plurality of measurable attributes;
determining whether the vehicular sustainability metric measured for the vehicle satisfies a set of sustainability criteria defined at least in part based on the measurable attributes of the vehicle; and
coating the surface of the vehicle with the first and the second coating if the vehicular sustainability metric satisfies the set of sustainability criteria.

2. The method of claim 1, wherein the gradient adaptor comprises at least one circuit.

3. The method of claim 2, wherein the circuit comprises a thermocouple.

4. The method of claim 2, wherein the circuit comprises a battery.

5. The method of claim 2, wherein the circuit comprises at least one sensor.

6. The method of claim 1, wherein at least one of the first coating or the second coating comprises paint.

7. The method of claim 1, wherein at least one of the first coating or the second coating comprises a film.

8. The method of claim 1, wherein at least one of the first coating or the second coating comprises a composite.

9. The method of claim 1, wherein at least one of the first coating or the second coating comprises an active coating.

10. The method of claim 1, wherein the first coating and the second coating form a layered coating.

11. The method of claim 1, wherein the first coating and the second coating is adjacent to each other.

12. The method of claim 1, wherein the surface comprises an internal surface of the vehicle.

13. The method of claim 1, wherein the surface comprises an external surface of the vehicle.

14. The method of claim 1, wherein the gradient property comprises an electromagnetic gradient.

15. The method of claim 1, wherein the gradient property comprises a biologic gradient.

16. The method of claim 1, wherein the gradient property comprises a thermal gradient.

17. The method of claim 1, wherein the gradient property comprises an acoustic gradient.

18. The method of claim 1, wherein the gradient property comprises a friction gradient.

19. The method of claim 1, wherein the gradient property comprises a chemical gradient.

20. The method of claim 1, wherein the vehicular sustainability metric comprises an operational efficiency.

21. The method of claim 1, wherein the set of sustainability criteria is further defined based at least in part on the gradient property.

22. The method of claim 1, further comprising changing at least one of the first coating or the second coating if the vehicular sustainability metric fails to satisfy the set of sustainability criteria.
